(19) United States
(12) Patent Application Publication
(10) Pub. No.: US 2022/0415670 A1
(43) Pub. Date: Dec. 29, 2022

(54) ADAPTER BOARD FOR PACKAGING AND METHOD MANUFACTURING THE SAME, AND SEMICONDUCTOR PACKAGING STRUCTURE

(71) Applicant: SJ Semiconductor(Jiangyin) Corporation, Jiangyin City (CN)

(72) Inventors: Yujie Yang, Jiangyin City (CN); Yuanjie Pan, Jiangyin City (CN); Zuyuan Zhou, Jiangyin City (CN); Chengchung Lin, Jiangyin City (CN)

(21) Appl. No.: 17/851,652

(22) Filed: Jun. 28, 2022

(30) Foreign Application Priority Data
Jun. 28, 2021 (CN) 202121445637.3
Jun. 28, 2021 (CN) CN 202110721421.3

(51) Int. Cl. H01L 21/48; H01L 21/768; H01L 21/02; H01L 23/48

(52) U.S. Cl. CPC H01L 21/486; H01L 21/76831; H01L 21/76885; H01L 21/02304; H01L 23/481

(57) ABSTRACT

The present disclosure provides an adapter board for semiconductor device packaging and a method manufacturing the same. The method includes: providing a stacked structure including a support substrate, a separation layer, and a silicon substrate, a TSV is formed in the silicon substrate, the TSV is filled with a copper conductive pillar, a diffusion barrier is formed between the copper conductive pillar and a side walls of the TSV; grinding a top surface of the silicon substrate; polishing a top surface of the remaining silicon substrate using a chemical mechanical polishing process until the TSV is exposed; etching the copper conductive pillar to form a groove; filling the groove with a protective layer; etching the top surface of the silicon substrate to expose the copper conductive pillar; forming an insulating layer on the top surface of the silicon substrate using a chemical vapor deposition process.

### CROSS REFERENCE TO RELATED APPLICATIONS

The present application claims the benefit of priority to Chinese Patent Application No. CN 202110721421.3, entitled “Adapter Board for Packaging and Method Manufacturing the Same, and Semiconductor Packaging Structure”, filed with CNIPA on Jun. 28, 2021, and Chinese Patent Application No. CN 202121445637.3, entitled “Adapter Board for Packaging and Semiconductor Packaging Structure”, filed with CNIPA on Jun. 28, 2021, the contents of which are incorporated herein by reference in their entireties.

### FIELD OF THE TECHNOLOGY

The present disclosure relates to the technical field of semiconductor packaging, in particular, to an adapter board for packaging and a method manufacturing the same, and a semiconductor packaging structure.

### BACKGROUND

With the development of electronic products towards miniaturization, high performance and high reliability, and the system integration level has been increasing. In this case, the way to improve the performance of electronic products by further reducing the feature size of integrated circuits and the line width of interconnect lines have become limited by the physical characteristics of materials and equipment processes, thus the traditional Moore's law is difficult to continue to be developed. Currently, advanced packaging methods include: Wafer Level Chip Scale Packaging (WLCSP), Fan-Out Wafer Level Package (FOWLP), Flip Chip, Package on Package (POP), etc. The 2.5D/3D integration technology with Through-Silicon Vias (TSVs) as the core has been widely regarded as the leading technology in the field of high-density packaging in the future and an effective way to break Moore's law.

Traditional 2.5D/3D packaging structure generally includes a silicon adapter board with TSVs, and copper conductive pillars are formed in the TSVs to interconnect chips with a substrates. The process of exposing the copper conductive pillars in the backsides of the TSVs is called Backside Via Reveal (BVR). The process generally includes: grinding a back surface of a silicon substrate which contains TSVs, chemical mechanical polishing (CMP) the silicon substrate back surface, and etching that back surface of the silicon substrate. These steps may lead to diffusion of copper from the TSVs into the silicon substrate and eventually lead to the degradation of the performance of the entire package structure.

FIGS. 1 to 6 show a process of manufacturing an adapter board for packaging in the existing techniques, and the process includes the following steps:

As shown in FIG. 1, a stacked structure 100 is provided. The stacked structure 100 includes a support substrate 101, a separation layer 102 disposed on the support substrate 101, and a silicon substrate 103 disposed on the separation layer 102. An exemplary TSV 104 extending vertically is formed in the silicon substrate 103, the TSV 104 is filled with a copper conductive pillar 105, and a diffusion barrier layer 106 is formed between the copper conductive pillar 105 and the side walls of the TSV hole 104.

Generally, the silicon substrate 103 is thick and the TSV 104 cannot penetrate the silicon substrate 103, so the silicon substrate 103 needs to be thinned, as shown in FIG. 2, and then the silicon substrate 103 is thinned. As the silicon substrate 103 is thinned until the TSV 104 is completely exposed, copper particles in the copper conductive pillar 105 are ground into the silicon substrate 103 around the TSV 104, as copper particles A in FIG. 2.

As shown in FIG. 3, a top surface of the stacked structure 100 is then polished using a CMP process. The polishing process further causes grinding of copper particles in the copper conductive pillar 105 into the silicon substrate 103 around the TSV 104, resulting in an increase in the concentration of copper particles A in the silicon substrate.

As shown in FIG. 4, a top surface of the silicon substrate 103 is then etched to expose the copper conductive pillar 105. As mentioned above, since the silicon substrate 103 around the TSV 104 is diffused with copper particles A in the copper conductive pillar 105, the silicon substrate 103 around the TSV 104 is not easily etched during etching of the silicon substrate 103, while etching of the silicon substrate 103 will then further cause the copper particles in copper conductive pillar 105 to diffuse into the silicon substrate 103 around the TSV 104, exacerbating the difficulty of etching the silicon substrate 103 around the TSV 104, thus creating silicon substrate etching defects.

As shown in FIG. 5, an insulating layer material 107 is then deposited on the top surface of the stacked structure 100 using a chemical vapor deposition process.

Finally, as shown in FIG. 6, the insulating layer material 107 is polished using a CMP process to expose the copper conductive pillar 105, while forming an insulating layer 108 covering the silicon substrate. As can be seen from the above steps, since the silicon substrate 103 around the TSV 104 is not easily etched, polishing the insulating layer material 107 will result in the insulating layer material 107 around the TSV 104 being ground, thus failing to provide insulation protection to the copper conductive pillar 105, leading to the risk of leakage and thus ultimately degrading the performance of the entire packaging structure.

### SUMMARY

The present disclosure provides an adapter board for packaging and a method manufacturing the same, and a semiconductor packaging structure, so the copper in the TSVs is not easy to diffuse into the silicon substrate during the preparation of the silicon adapter board of the 2.5D/3D packaging structure, which eventually improve the performance of the entire packaging structure.

The method for manufacturing the adapter board for packaging includes: providing a stacked structure, the stacked structure includes a support substrate, a separation layer disposed on the support substrate, and a silicon substrate disposed on the separation layer, a Through-Silicon Via (TSV) extending vertically is formed in the silicon substrate, the TSV is filled with a copper conductive pillar, a diffusion barrier is formed between the copper conductive pillar and a side walls of the TSV; grinding a top surface of the silicon substrate until the TSV is exposed; polishing a top surface of the stacked structure using a chemical mechanical polishing process; etching the copper conductive pillar to a predetermined depth using a wet etching process to form an etching groove, and removing copper ground into a surface of the silicon substrate using a wet etching solution; filling the groove with a protective layer; etching the top surface of the silicon substrate to expose the copper conductive pillar; forming an insulating layer on the top surface of the silicon substrate using a chemical vapor deposition process.

Optionally, the wet etching solution is a copper etching solution and includes phosphoric acid and hydrogen peroxide.

Optionally, forming the stacked structure includes: providing the silicon substrate; forming the TSV in the silicon substrate; forming the diffusion barrier layer on the side walls of the TSV; filling the TSV with copper material to form the copper conductive pillar; and providing the support substrate and the separation layer, and bonding the support substrate to a side of the silicon substrate having the TSV through the separation layer to form the stacked structure.

Optionally, forming the protective layer includes: depositing a protective layer material on the top surface of the stacked structure using a chemical vapor deposition process until filling the etching groove; and polishing the top surface of the stacked structure to the top surface of the silicon substrate using a chemical mechanical polishing process to form the protective layer covering a top surface of the copper conductive pillar.

Optionally, forming the insulating layer includes: depositing an insulating layer material on the top surface of the stacked structure using a chemical vapor deposition process; and polishing the insulating layer material and the protective layer using a chemical mechanical polishing process to expose the copper conductive pillar to form the insulating layer covering the silicon substrate.

Optionally, a depth of the groove is between 1% and 2% of the length of the copper conductive pillar, and the material of the protective layer includes silicon oxide.

The present disclosure further provides an adapter board for packaging. The adapter board for packaging includes a separation layer, a support substrate, a silicon substrate, a TSV penetrating part of the silicon substrate, a copper conductive pillar, a diffusion barrier, and an insulating layer. The support substrate and the silicon substrate diffusion barrier, and an insulating layer. The support substrate and the silicon substrate are respectively bonded to a top surface and a bottom surface of the separation layer. The copper conductive pillar fills the TSV and protrudes from the TSV, copper particles in the copper conductive pillar do not diffuse into a surface of the silicon substrate. The diffusion barrier is formed between the copper conductive pillar and a side walls of the TSV and extends flush with the copper conductive pillar. The insulating layer is formed on the surface of the silicon substrate and covers a circumference of the copper conductive pillar.

Optionally, the support substrate includes one of a glass substrate, a metal substrate, a semiconductor substrate, a polymer substrate, and a ceramic substrate; the separation layer includes a polymer layer or an adhesive layer.

Optionally, the diffusion barrier layer includes one or a stack of at least two of a tantalum nitride layer, a titanium nitride layer, a silicon nitride layer, and a silicon oxide layer.

Optionally, the insulating layer includes one or a stack of two of a silicon nitride layer and a silicon oxide layer.

The present disclosure further provides a semiconductor packaging structure, including the adapter board for packaging as described in any one of the above.

As mentioned above, the present disclosure provides an adapter board for packaging and a method for manufacturing the same, and a semiconductor packaging structure. By forming the groove using a wet etching process, copper particles diffused into the surface of the silicon substrate in the previous process can be removed, and the groove can be used for the subsequent deposition of protective layer on the surface of the copper conductive pillar. In addition, the groove combined with the protective layer that fills the groove in the subsequent process can effectively prevent copper particles from diffusing into the silicon substrate during the etching of the silicon substrate. This avoids the possibility of diffusion of all copper conductive pillars into the silicon substrate during the entire manufacturing process of tin, e adapter board, effectively improving the performance of the packaging structure.

### BRIEF DESCRIPTION OF THE DRAWINGS

FIGS. 1 to 6 show schematic cross sectional views of the structures after each step of a manufacturing process of an adapter board for packaging in the existing technique.

FIG. 7 shows a schematic flowchart of a method for manufacturing an adapter board for packaging according to Embodiment 1 of the present disclosure.

FIGS. 8 to 19 show schematic cross sectional views of the structures after each step of the method for manufacturing an adapter board for packaging according to Embodiment I of the present disclosure; FIG. 19 also shows a schematic structural diagram of an adapter board for packaging according to Embodiment 2 of the present disclosure.

### DESCRIPTION OF THE REFERENCE NUMERALS

| | |
|---|---|
| 100, 200 | Stacked structure |
| 101, 201 | Support substrate |
| 102, 202 | Separation layer |
| 103, 203 | Silicon substrate |
| 104, 204 | TSV |
| 105, 205 | Copper conductive pillar |
| 106, 206 | Diffusion barrier |
| 107, 210 | Insulating layer material |
| 108, 211 | Insulating layer |
| 207 | Etching groove |
| 208 | Protective layer material |
| 209 | Protective layer |
| A | Copper particles |
| D | Depth of etching groove |
| S1~S7 | Steps |

### DESCRIPTION OF THE EMBODIMENTS

The embodiments of the present disclosure will be described below through specific embodiments. Those skilled in the art can easily understand other advantages and effects of the present disclosure according to contents disclosed by the specification. The present disclosure can also be implemented or applied through other different specific implementation modes. Various modifications or changes can also be made to all details in the specification based on different points of view and applications without departing from the spirit of the present disclosure.

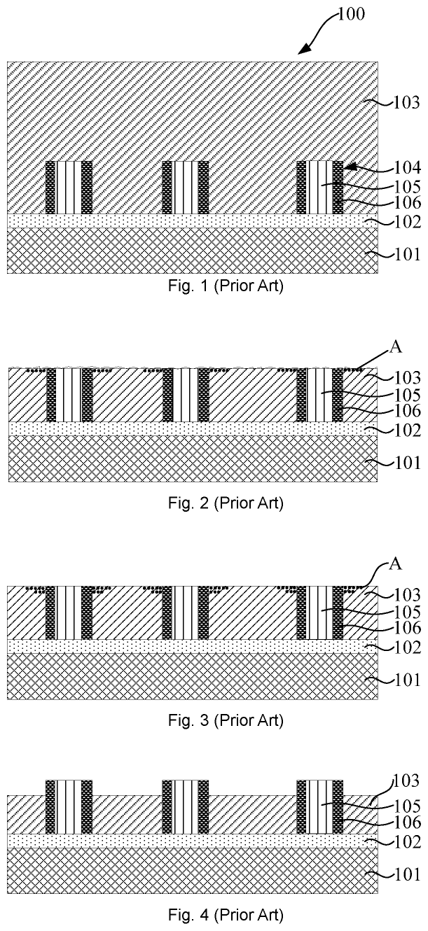

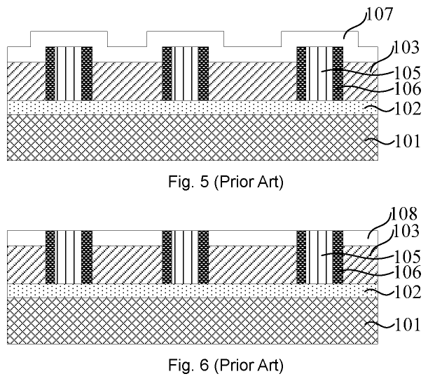

Refer to FIGS. 1 to 19. It needs to be stated that the drawings provided in the following embodiments are just used for schematically describing the basic concept of the present disclosure, thus only illustrating components related to the present disclosure and are not drawn according to the numbers, shapes and sizes of components during actual implementation, the configuration, number and scale of each component during actual implementation thereof may be freely changed, and the component layout configuration thereof may be more complex.

### Embodiment 1

The present disclosure provides a method for manufacturing an adapter board for packaging, to prevent copper particles diffusing from copper conductive pillars to a silicon substrate. The method is described as follows.

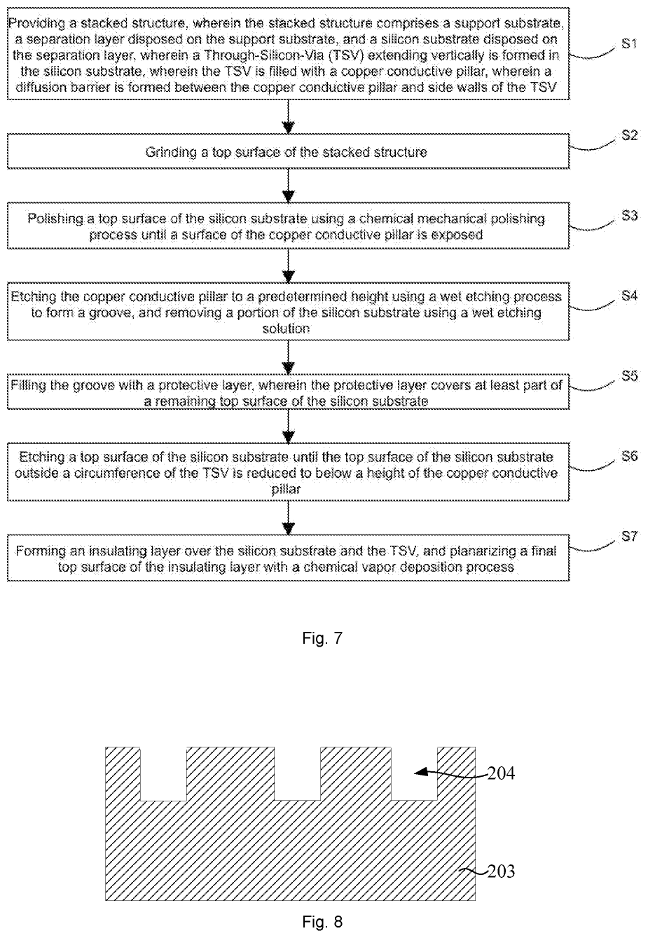

As shown in FIGS. 7 and 11, step S1 is performed: a stacked structure 200 is provided, the stacked structure 200 includes a support substrate 201, a separation layer 202 disposed on the support substrate 201, and a silicon substrate 203 disposed on the separation layer 202, an exemplary TSV 204 extending vertically is formed in the silicon substrate 203, the TSV 204 is filled with a copper conductive pillar 205. A diffusion barrier 206 is formed between the copper conductive pillar 205 and side walls of the TSV 204.

By way of example, the support substrate 201 includes one of a glass substrate, a metal substrate, a semiconductor substrate, a polymer substrate, and a ceramic substrate. In this embodiment, the support substrate 201 is a glass substrate, the glass substrate has low costs, it is easy to form a separation layer 202 on the surface of the glass substrate, and the difficulty of the subsequent peeling process can be reduced.

The separation layer 202 is disposed between the silicon substrate 203 and the support substrate 201, and is preferably made of an adhesive material with a smooth surface such that the separation layer 202 has a seamless bonding contact with the silicon substrate 203 to ensure that the silicon substrate 203 in the subsequent processes will not shift, and the separation layer 202 also has a strong bonding force with the support substrate 201. Generally, the bonding force between the separation layer 202 and the support substrate 201 needs to be greater than the bonding force between the separation layer 202 and the silicon substrate 203. As an example, the separation layer 202 includes a polymer layer or adhesive layer, and the polymer layer or adhesive layer is first applied to a surface of the support substrate 201 by a spin-coating process and then cured by a UV-curing or heat-curing process.

In this embodiment, the polymer layer includes an LTHC photothermal conversion layer, and the LTHC photothermal conversion layer can be subsequently heated using a laser when peeling the support substrate 201 to separate the silicon substrate 203 and the support substrate 201 from each other at the LTHC photothermal conversion layer.

As an example, the diffusion barrier 206 includes one or a stack of at least two of a tantalum nitride layer, a titanium nitride layer, a silicon nitride layer and a silicon oxide layer.

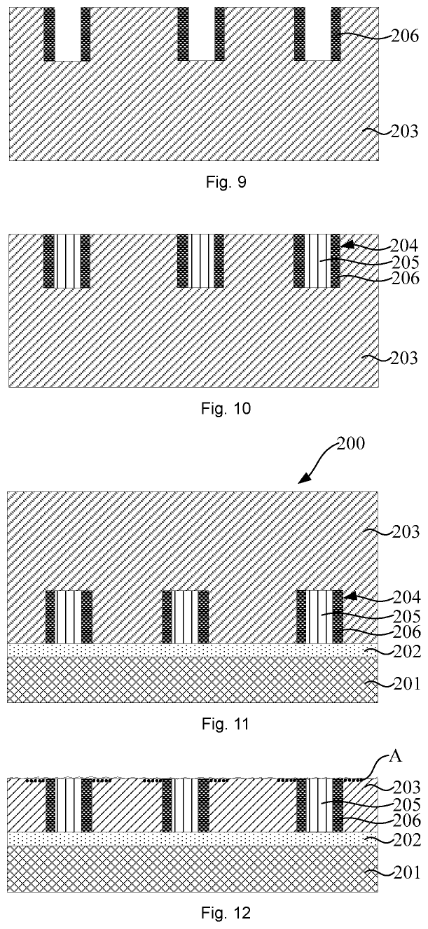

As shown in FIGS. 8 to 11, as an example, the steps of forming the stacked structure 200 include: providing the silicon substrate 203, and forming the TSV 204 in the silicon substrate 203, the TSV 204 is a blind hole not penetrating the entire silicon substrate 203, as shown in FIG. 8; forming the diffusion barrier 206 on the side walls of the TSV 204, as shown in FIG. 9; filling the TSV 204 with copper material to form the copper conductive pillar 205, as shown in FIG. 10; providing the support substrate 201 and the separation layer 202, and bonding the support substrate 201 to the side of the silicon substrate 203 having the TSV 204 using the separation layer 202 to form the stacked structure 200, as shown in FIG. 11.

As shown in FIGS. 8 and 12, step S2 is performed, a top surface of the silicon substrate 203 is ground until the TSV 204 is exposed. As the silicon substrate 203 is thinned until the TSV 204 is exposed, copper particles are ground from the copper conductive pillar 205 into the silicon substrate 203 around the TSV 204, such as copper particles A in FIG. 12.

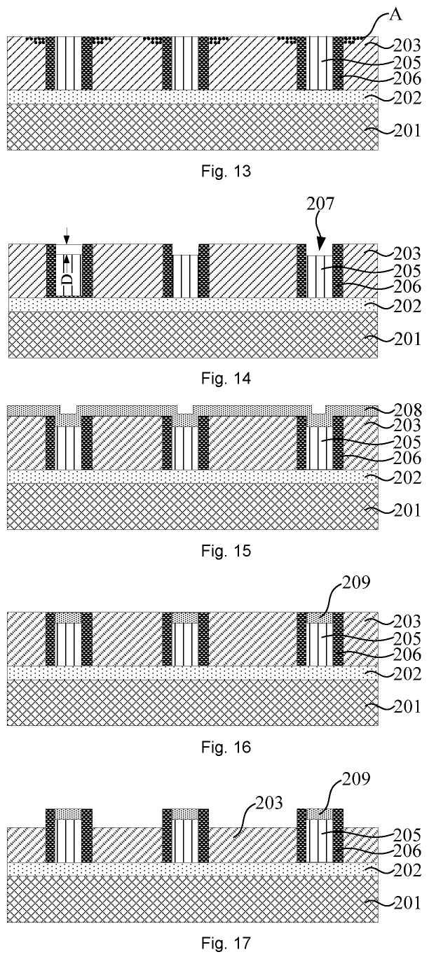

As shown in FIGS. 8 and 13, step S3 is performed, a top surface of the stacked structure 200 is polished using a CMP process. And during this polishing process, copper particles in the copper conductive pillar 205 will be further ground into the silicon substrate 203 around the circumference of TSV 204, so that the concentration of copper particles A in the silicon substrate increases.

As shown in FIGS. 8 and 14, step S4 is performed, the copper conductive pillar 205 is etched to a predetermined depth using a wet etching process to form a groove 207, while a wet etching solution removes the copper grounded into the surface of the silicon substrate 203.

The groove 207 is formed using the wet etching process, first, copper particles diffused into the surface of the silicon substrate 203 in the previous process can be removed; further, the groove 207 provides a recessed place for the subsequent deposition of a protective layer on the surface of the copper conductive pillar 205. As an example, the etching solution used in the wet etching process can be any existing copper etching solution suitable for etching copper particles, the preferred wet etching solution in this embodiment includes phosphoric acid and hydrogen peroxide, hydrogen peroxide can oxidize copper to copper oxide, while phosphoric acid can etch off copper oxide, so as to achieve the etching of the copper conductive pillar 105. As an example, the depth D of the groove 207 is between 1% and 2% of the height of the copper conductive pillar 205, for example, when the height of the copper conductive pillar is 100 μm, the depth D of the groove generally ranges from 1 μm to 2 μm.

As shown in FIGS. 8 to 16, step S5 is then performed, the etched groove 237 is filled with a protective layer 209. The copper conductive pillar 205 can be protected from etching by the protective layer 209 during subsequent etching of the silicon substrate 203, thereby avoiding the diffusion of copper particles from the copper conductive pillar 205 into the silicon substrate 203 during etching of the silicon substrate 203.

As shown in FIGS. 15 to 16, as an example, forming the protective layer 209 includes: depositing a protective layer material 208 on the top surface of the stacked structure 200 using a chemical vapor deposition process to fill the etched groove 207, as shown in FIG. 15; and polishing the top surface of the stack structure 200 to the top surface of the silicon substrate 203 using a CMP process to form the protective layer 209 covering the top surface of the copper conductive pillar 205, as shown in FIG. 16.

As an example, the material of the protective layer 209 may include silicon etching protection materials which have a good etching selection ratio versus silicon. Preferably, the material of the protection layer in this embodiment is silicon oxide.

As shown in FIGS. 8 and 17, step S6 is then performed, the top surface of the silicon substrate 203 outside the TSV structure is etched to be below the top surface level of the copper conductive pillar 205. During this step, since the diffusion barrier 206 is disposed on the side walls of the copper conductive pillar 205 and the protective layer 209 is disposed on the top surface of the copper conductive pillar 205, the etching does not affect the copper conductive pillar 205, and the diffusion of copper particles into the silicon substrate is avoided. Thus, the effectiveness of the silicon substrate etching process is ensured. As an example, a dry etching method can be used to etch the silicon substrate 203.

As shown in FIGS. 8 and 19, step S7 is performed, an insulating layer 211 is formed on the top surface of the silicon substrate 203 outside the TSV structure using a chemical vapor deposition process.

As an example, the insulating layer 211 may be a single layer or a stacked layer, for example, the insulating layer 211 may be a single layer structure of silicon nitride or silicon oxide or a stacked layer structure of silicon oxide and silicon nitride.

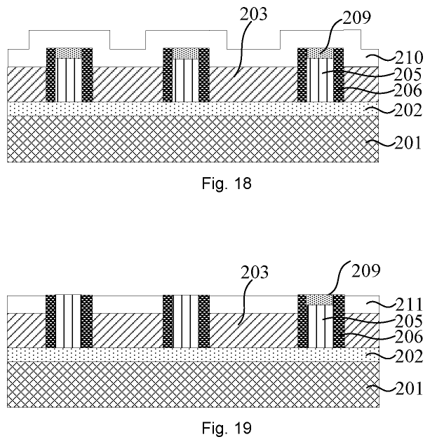

As shown in FIGS. 18 and 19, as an example, forming the insulating layer 211 includes: depositing an insulating layer material 210 on the top surface of the stacked structure 200 using a chemical vapor deposition process, as shown in FIG. 18; and polishing the insulating layer material 210 and the protective layer 209 using a CMP process to expose the copper conductive pillar 205 to form an insulating layer 211 covering the silicon substrate 203, as shown in FIG. 19.

In this embodiment, by forming the groove 207 using a wet etching process, copper particles diffused into the surface of the silicon substrate 203 in the previous process can be removed, and the groove 207 can provide a space for the subsequent deposition of a protective layer on the outer surface of the copper conductive pillar 205. In addition, the groove 207 combined with the protective layer 209 that fills the groove 207 in the subsequent process can effectively prevent copper particles from diffusing into the silicon substrate 203 during the etching of the silicon substrate 203. This avoids the possibility of diffusion of all copper conductive pillars into the silicon substrate during the entire manufacturing process of the adapter board, effectively improving the performance of the packaging structure.

### Embodiment 2

This embodiment provides an adapter board for packaging, the adapter board is manufactured using the method in Embodiment 1, the beneficial effects can be seen in Embodiment 1 and will not be repeated in the following.

As shown in FIG. 19, the adapter board for packaging includes a support substrate 201, a separation layer 202, a silicon substrate 203, a TSV 204, a copper conductive pillar 205, a diffusion barrier 206, a groove 207, a protective layer 209, and an insulating layer 211. The support substrate 201 is bonded a top surface and the silicon substrate 203 is bonded to a bottom surface of the separation layer 202. The TSV 204 is disposed vertically in the silicon substrate 203. The copper conductive pillar 205 fills the TSV 204 and protrudes from the TSV 204 and copper particles in the copper conductive pillar 205 do not diffuse into a surface of the silicon substrate 203. The diffusion barrier 206 is disposed between the copper conductive pillar 205 and the side walls of the TSV 204 and extends to be flush with the copper conductive pillar 205. The groove 207 is disposed at one end of the copper conductive pillar 205 inside the sidewalls of the diffusion barrier 206 in the TSV 204. The protective layer 209 fills in the groove 207. The insulating layer 211 is formed on a surface of the silicon substrate 203 and covers the circumference of the copper conductive pillar 205.

As an example, the support substrate 201 includes one of a glass substrate, a metal substrate, a semiconductor substrate, a polymer substrate, and a ceramic substrate; the separation layer 202 includes a polymer layer or an adhesive layer.

As an example, the diffusion barrier 206 includes one or a stack of at least two of a tantalum nitride layer, a titanium nitride layer, a silicon nitride layer and a silicon oxide layer.

As an example, the insulating layer 211 includes one or a stack of two of a silicon nitride layer and a silicon oxide layer.

This embodiment further provides a semiconductor packaging structure, and the semiconductor packaging structure includes the adapter board for packaging as described above.

In summary, the present disclosure proposes an adapter board for packaging and a method for manufacturing the same, and a semiconductor packaging structure. By forming the groove using a wet etching process, copper particles diffused into the surface of the silicon substrate in the previous process can be removed, and the groove can be used for the subsequent deposition of protective layer on the surface of the copper conductive pillar. In addition, the groove combined with the protective layer that fills the groove in the subsequent process can effectively prevent copper particles from diffusing into the silicon substrate during the etching of the silicon substrate. This avoids the possibility of diffusion of all copper conductive pillars into the silicon substrate during the entire manufacturing process of the adapter board, effectively improving the performance of the packaging structure. Therefore, the present disclosure effectively overcomes the shortcomings of the prior art and has a high industrial use value.

While particular elements, embodiments, and applications of the present invention have been shown and described, it is understood that the invention is not limited thereto because modifications may be made by those skilled in the art, particularly in light of the foregoing teaching. It is therefore contemplated by the appended claims to cover such modifications and incorporate those features which come within the spirit and scope of the invention.

What is claimed is:

1. A method for manufacturing an adapter board for packaging, comprising:
providing a stacked structure, wherein the stacked structure comprises a support substrate, a separation layer disposed on the support substrate, and a silicon substrate disposed on the separation layer, wherein a Through-Silicon-Via (TSV) extending vertically is formed in the silicon substrate, wherein the TSV is filled with a copper conductive pillar, wherein a diffusion barrier is formed between the copper conductive pillar and side walls of the TSV;
grinding a top surface of the stacked structure;
polishing a top surface of the silicon substrate using a chemical mechanical polishing process until a surface of the copper conductive pillar is exposed;
etching the copper conductive pillar to a predetermined height using a wet etching process to form a groove, and removing a portion of the silicon substrate using a wet etching solution;
filling the groove with a protective layer, wherein the protective layer covers at least part of a remaining top surface of the silicon substrate;
etching a top surface of the silicon substrate until the top surface of the silicon substrate outside a circumference of the TSV is reduced to below a height of the copper conductive pillar; and
forming an insulating layer over the silicon substrate and the TSV, and planarizing a final top surface of the insulating layer with a chemical vapor deposition process.

2. The method for manufacturing the adapter board for packaging according to claim 1, wherein the wet etching comprises a copper etching solution which includes phosphoric acid and hydrogen peroxide.

3. The method for manufacturing the adapter board for packaging according to claim 1, wherein forming the stacked structure includes:
providing the silicon substrate;
forming the TSV in the silicon substrate;
forming the diffusion barrier layer on the side walls of the TSV;
filling on the diffusion barrier layer inside the TSV with a copper material to form the copper conductive pillar; and
providing the support substrate and the separation layer, and bonding the support substrate to a side of the silicon substrate to form the stacked structure.

4. The method for manufacturing the adapter board for packaging according to claim 1, wherein forming the protective layer further comprises:
depositing a protective layer material using a chemical vapor deposition process until filling the etching groove; and polishing the protective layer on the silicon substrate using a chemical mechanical polishing process to form a top surface of the protective layer on the copper conductive pillar.

5. The method for manufacturing the adapter board for packaging according to claim 1, wherein forming the insulating layer comprises:
depositing an insulating layer material over the top surface of the silicon substrate using a chemical vapor deposition process; and
polishing the insulating layer material and the protective layer under the insulating layer using a chemical mechanical polishing process to have the protective layer on the copper conductive pillar.

6. The method for manufacturing the adapter board for packaging according to claim 1, wherein a depth of the groove is between 1% and 2% of the height of the copper conductive pillar, and wherein a material of the protective layer includes silicon oxide.

7. An adapter board for packaging, comprising:
a separation layer;
a support substrate bonded to a top surface and a silicon substrate bonded to a bottom surface of the separation layer respectively;
a TSV, disposed vertically in the silicon substrate;
a copper conductive pillar, filling the TSV;
a diffusion barrier, disposed between the copper conductive pillar and side walls of the TSV;
a groove, disposed at one end of the copper conductive pillar inside the sidewalls of the diffusion barrier in the TSV;
a protective layer, filling in the groove; and
an insulating layer, disposed on a top surface of the protective layer, a top surface of the sidewalls, and a top surface of the silicon substrate outside of a circumference of the TSV.

8. The adapter board for packaging according to claim 7, wherein the support substrate comprises one of a glass substrate, a metal substrate, a semiconductor substrate, a polymer substrate, and a ceramic substrate; wherein the separation layer comprises a polymer layer or an adhesive layer.

9. The adapter board for packaging according to claim 7, wherein the diffusion barrier layer comprises one or a stack of at least two of a tantalum nitride layer, a titanium nitride layer, a silicon nitride layer, and a silicon oxide layer.

10. The adapter board for packaging according to claim 7, wherein the insulating layer comprises one or a stack of two of a silicon nitride layer and a silicon oxide layer.

11. A semiconductor packaging structure, comprising an adapter board for packaging, wherein the adapter board for packaging comprises:
a separation layer;
a support substrate bonded to a top surface of the separation layer and a silicon substrate bonded to a bottom surface of the separation layer respectively;
a TSV disposed vertically in the silicon substrate;
a copper conductive pillar, filling the TSV and protruding from the TSV, wherein copper particles in the copper conductive pillar do not diffuse into a surface of the silicon substrate;
a diffusion barrier formed between the copper conductive pillar and side walls of the TSV, wherein the diffusion barrier wraps around the copper conductive pillar; and
an insulating layer, formed on the surface of the silicon substrate and covering a circumference of the copper conductive pillar.
